(19) United States
(12) Patent Application Publication
(10) Pub. No.: US 2010/0028556 A1
(43) Pub. Date: Feb. 4, 2010

(54) CHEMICAL VAPOR DEPOSITION COLORED DIAMOND

(75) Inventors: Robert C. Linares, Sherborn, MA (US); Patrick J. Doering, Holliston, MA (US)

Correspondence Address: SCHWEGMAN, LUNDBERG & WOESSNER, P.A., P.O. BOX 2938, MINNEAPOLIS, MN, 55402, US

(73) Assignee: Apollo Diamond Gemstone Corporation, Framingham, MA (US)

(21) Appl. No.: 12/463,115

(22) Filed: May 8, 2009

Related U.S. Application Data
(60) Provisional application No. 61/051,896, filed on May 9, 2008.

(51) Int. Cl. B05D 3/06; C23C 16/56

(52) U.S. Cl. 427/535; 427/249.14

(57) ABSTRACT

Chemical vapor deposition grown diamonds may be provided with one or more layers of doping to form colored diamonds. In one embodiment, layers of pink colored diamond may be formed by doping with nitrogen. In further embodiments, layers of yellow colored diamond may be formed by doping with boron. In some embodiments, the grown diamond has a single crystalline structure with minimal to no grain boundaries.

### CROSS-REFERENCE TO RELATED APPLICATIONS

This application claims priority to U.S. Provisional Application Ser. No. 61/051,896, filed May 9, 2008, the entire disclosure of which is incorporated by reference herein.

### BACKGROUND

Colored diamond found in nature often consists of layers of colorless and colored diamond. Moreover, the color found in some diamonds is at least partially attributed to defects and/or specific doping in the colored layer. Using the high pressure/high temperature process to form diamonds, it is not currently believed possible to engineer a method to produce such alternating layers since the process cannot be interrupted to modify defects or doping to produce such layers.

Boron doping in chemical vapor deposition (CVD) grown diamonds is known to produce a blue color in the grown diamond. Some grown diamonds have been doped with boron throughout the diamond to form blue colored surgical blades. Such doping has also been used as a coating on an outer or inner layer to form a colored surgical blade. Whole diamonds or individual layers can be made to have a blue coloration which ranges from sky blue to very dark blue by adding boron to the precursor gas to yield boron concentrations ranging from about 0.05 ppma to about 3000 ppma in the diamond, respectively. In such films, the optical absorption for wavelengths from 450 nm to 7 μm will increase as the doping level is increased and as the thickness is increased.

### BRIEF DESCRIPTION OF THE DRAWINGS

FIG. 1 is a block cross section representation of a chemical vapor deposition grown diamond with one or more colored layers according to an example embodiment.

FIG. 2 is a graph of a typical absorption spectrum for boron doped diamond according to an example embodiment.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

Chemical vapor deposition (CVD) grown diamonds may be provided with one or more layers of doping to form colored diamonds. In one embodiment, layers of pink colored diamond may be formed by doping with nitrogen. In further embodiments, layers of blue colored diamond may be formed by doping thin layers with boron, alternated with low doped or undoped CVD diamond layers. In some embodiments, the grown diamond has a single crystalline structure with minimal to no grain boundaries. The CVD process can be manipulated to produce layers of varied composition or color since the controlling parameters such as growth temperature or gas composition can be readily changed in a controlled manner during the process.

In further embodiments, one or more pink layers may be modified by annealing or by irradiation such as by electrons. Irradiation may create vacancies, that can be moved to nitrogen centers by annealing. The color of a layer may be altered by changing the number of nitrogen vacancy centers to provide yet a further level of control of the color of the layer.

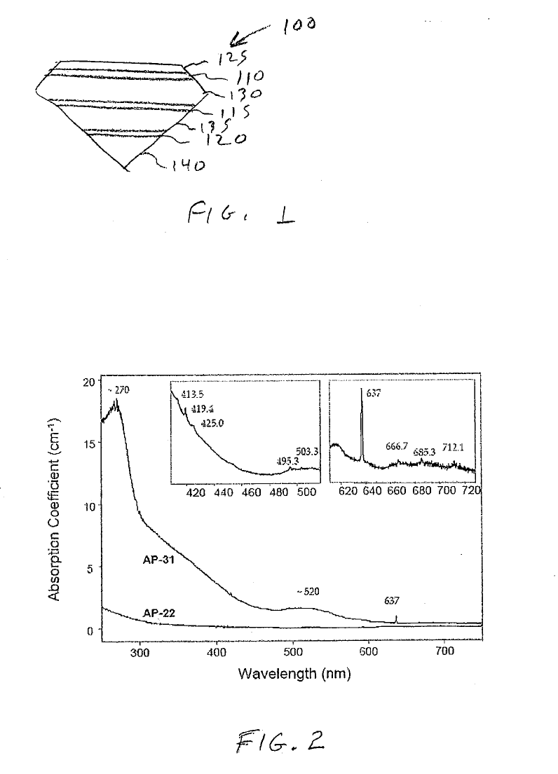

A block cross section diagram of a chemical vapor deposition grown diamond gemstone 100 shows one or more layers 110, 115 and 120 formed with doping to provide desired colors. In one embodiment, high nitrogen doped layers 110, 115, and 120 may be formed during growth of the diamond 100 by adding pure nitrogen or a nitrogen containing gas such as ammonia or air during the growth to form nitrogen impurities in the grown diamond. The high doping layers in one embodiment have doping of 0.1-10 ppm nitrogen concentration, providing sufficient yellow coloration, and the amount (saturation) of pink color may be further increased by adding more layers. In one embodiment, the layers are formed inside of a diamond plate that is grown, and then cut such as by a laser and optionally polished to form the diamond illustrated at 100 in FIG. 1. Layers of diamond between the one or more colored layers, such as layers 125, 130, 135 and 140 may be formed with low nitrogen doping, such as nitrogen levels less than approximately 50 ppb. This level of doping is referred to as undoped, and may appear colorless or near colorless. By varying both the thickness and nitrogen doping level, the depth of color, or saturation can be varied and controlled.

In one embodiment, several alternating layers of both high and low nitrogen doped layers may be formed throughout the diamond. In further embodiments, one or more internal high nitrogen doped layers may be formed. The high number of alternating layers tends to look more like natural pink, yellow or blue diamond (boron doped).

Thicknesses of the high doped nitrogen layers may be varied between less than 1 um to 1 mm in some embodiments. Typically, such layers are approximately 20 to 50 μm in thickness to provide a nice pink solid layer. In some embodiments, the grown diamond is formed with a <100> orientation plus or minus 10 degrees.

In natural colored diamonds color banding tends to be found on the <111> growth planes. Diamond gemstones are usually cut with the table close to the <100> plane. The consequence of this is that in natural colored gems, the color bands can frequently be seen through the table of the stone producing an undesirable effect. In CVD grown stones, the growth occurs on or near the <100> planes and the color banding is therefore parallel to the <100> plane. Since the table is cut closely parallel to the <100> plane, the view from the table looks perpendicular to the color bands and they can not be seen, leading to a colored gemstone having a highly desirable uniform colored stone.

Using the CVD processes to grow diamond, it is possible to grow alternating layers of a particular doping level or defect level. As described above, pink diamonds can be grown using nitrogen doping. The pink color in CVD diamond is attributed to a combination of nitrogen vacancy centers (in which substitutional nitrogen is adjacent to a carbon vacancy, and other defects). A typical absorption spectrum of a pink CVD grown diamond is shown in FIG. 2. The inclusion of nitrogen at high levels leads to a more defective layer than the undoped or lightly doped layers. Such a diamond composite will therefore consist of layers of doped and undoped and undoped diamond as well defective and less defective layers. Such a structure more closely emulates natural diamond than a diamond with one composition.

Another example utilizes layers of boron doped diamond along with layers of undoped diamond to achieve a blue color. The addition of boron to the diamond lattice introduces strain and decreases the growth rate. The growth of a thin layer of boron doped diamond (under strain) followed by a layer of undoped diamond, balances out the strain and permits the growth of a relatively thick blue diamond with a good color, a commercially high enough growth rate and good crystal quality. The intensity of the blue color (saturation) can be controlled by the boron level, the thickness of the boron layer, the number of layers and the overall thickness of the stone.

In one embodiment, the boron doped layers are doped with boron in the range of 0.5 ppm to 1000 ppm. The layers of boron doped diamond are formed with a thickness of less than 1 μm to 50 μm in one embodiment, followed with an undoped layer to relieve the strain. The total amount of boron doping in the grown diamond may determine the tint of blue, with increased total doping encountered by light passing through the diamond creating a darker blue color. To achieve the darker blue color, high doped thinner layers may be used with alternating thin layers of undoped diamond. The use of such thinner layers allows the total amount of boron doping and hence the color intensity to be increased while maintaining the structural integrity of the grown diamond by relieving the strain with undoped layers.

The same can be said about the pink layers. In addition, nitrogen can be added in such a manner to achieve a pure substitutional nitrogen without an adjacent carbon vacancy, in which the stones will be yellow. A typical optical absorption spectrum of a yellow diamond is shown in FIG. 2. In further embodiments, colors such as green may be formed by growing alternating layers of yellow and blue diamond.

In further embodiments, pink, yellow, yellow-green and diamonds can be produced directly by the CVD method and varying the dopant from layer to layer and annealing the diamonds with varied parameters. In still a further embodiment, pink and green layers may be alternated to form purple diamonds.

Heat may be used to adjust the color, hue, defect density and color saturation. In one embodiment, annealing is performed by using heat to diffuse vacancies. Temperatures of about 700 to 1000° C. may be used to diffuse the vacancies. The vacancies may diffuse to form nitrogen vacancies in one embodiment. In further embodiments, higher heats, such as temperatures in the 1700 to 2500° C. level may be used to destroy nitrogen vacancies. Times for such heat treatments may range from seconds to hours in some embodiments. Shorter and longer times may be used if they provide desired coloration. In some embodiments, the heat treatments/annealing may be done in a vacuum, an inert atmosphere, or in a hydrogen atmosphere. Heating in a hydrogen plasma may result in a different coloration than heating in a vacuum.

For temperatures above approximately 1700° C., suitable pressure may be applied to the diamond to ensure it stays within a stability range. Such temperatures can tend to turn the diamond into graphite absent suitable pressure. Annealing at such temperatures may result in destruction of vacancies along with a resulting color of yellow or green. The color may be further modified by irradiation as described above and annealing again at various temperatures to move vacancies.

In various embodiments, gemstones generally should have a thickness of 0.5 mm or thicker, with no actual upper limit. Thickness may be determined by the area of the crystal which will lead to a cut gemstone of optimized beauty and color. The nitrogen content may be varied between 50 to 100 ppm in one example, and heat and irradiation treatments may be used to vary the number of nitrogen vacancies and hence the color of the resulting diamond. In further embodiments, the highly doped layers may have a nitrogen content of between 0.1 to 100 ppm.

The Abstract is provided to comply with 37 C.F.R. §1.72(b) to allow the reader to quickly ascertain the nature and gist of the technical disclosure. The Abstract is submitted with the understanding that it will not be used to interpret or limit the scope or meaning of the claims.

What is claimed is:

1. A method of forming a colored diamond, the method comprising:
growing alternating layers of diamond with high and low nitrogen doping using chemical vapor deposition, such that at least some of the high nitrogen doped layers are internal to the grown diamond.

2. The method of claim 1 wherein the high nitrogen doping is in the range of 0.1 to 10 ppm.

3. The method of claim 1 wherein the nitrogen doped layers have a thickness in the range of 1 um to 1 mm.

4. The method of claim 1 wherein three or more high doped layers are formed.

5. The method of claim 1 wherein the diamond is grown as a plate that can be cut into gemstones, and wherein the gemstones have tables and doped layers substantially parallel to the <100> plane.

6. The method of claim 1 and further comprising irradiating the high doped layers.

7. The method of claim 1 and further comprising annealing one or more high doped layers.

8. The method of claim 7 wherein the annealing is performed at temperatures between 700 and 1000° C.

9. The method of claim 8 wherein the annealing is performed for approximately 30 minutes to an hour.

10. The method of claim 7 wherein the annealing is performed at a temperature of approximately 1700° C. or higher.

11. The method of claim 10 wherein the annealing is performed in a vacuum, inert atmosphere, or hydrogen plasma.

12. A method of forming a colored diamond, the method comprising:
growing alternating layers of diamond with high and low boron doping using chemical vapor deposition, such that at least some of the high boron doped layers are internal to the grown diamond.

13. The method of claim 12 and further comprising including at least one nitrogen doped layer in the grown diamond and annealing one or more of the nitrogen doped layers.

14. The method of claim 13 wherein the annealing is performed at temperatures between 700 and 1000° C.

15. The method of claim 13 wherein the annealing is performed at a temperature of approximately 1700° C. or higher.

16. The method of claim 15 wherein the annealing is performed in a vacuum, inert atmosphere, or hydrogen plasma.

17. A method of forming a colored diamond, the method comprising:
growing alternating layers of diamond with high and low nitrogen doping using chemical vapor deposition, such that at least some of the high nitrogen doped layers are internal to the grown diamond; and
further growing layers of diamond with high boron doping between one or more of the high and low nitrogen doped layers.

18. The method of claim 17 wherein the colored diamond is green.

19. The method of claim 17 wherein the colored diamond is purple.

20. The method of claim 17 and further comprising:
irradiating one or more of the nitrogen doped layers; and
annealing one or more of the nitrogen doped layers to change the color of such layers.
